(19) United States
(12) Patent Application Publication
(10) Pub. No.: US 2005/0287698 A1
(43) Pub. Date: Dec. 29, 2005

(54) Use of chalcogen plasma to form chalcogenide switching materials for nanoscale electronic devices

(76) Inventors: Zhiyong Li, Palo Alto, CA (US); Shih-Yuan Wang, Palo Alto, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/878,921

(22) Filed: Jun. 28, 2004

(51) Int. Cl. H01L 21/06

(52) U.S. Cl. 438/102

(57) ABSTRACT

A method of forming a metal chalcogenide. A metal is provided and exposed to a chalcogen plasma to form the metal chalcogenide.

### FIELD OF THE INVENTION

The present invention relates to an electronic device having a functional length scale that is measured in nanometers. More specifically, the present invention relates to forming a metal chalcogenide material for use in a nanometer scale (nanoscale) electronic device.

### BACKGROUND OF THE INVENTION

The silicon integrated circuit has dominated electronics and has helped the industry grow to become one of the world's largest and most critical industries. However, due to a combination of physical and economic reasons, the miniaturization that has accompanied the growth of silicon integrated circuits is reaching its limit. The present scale of electronic devices is on the order of tenths of micrometers (μm). However, new solutions are being proposed to form electronic devices on an ever smaller scale, such as a nanometer (nm) scale.

Organic molecules, such as rotaxane or catenane compounds, have been used to form electronic switches in nanoscale electronic devices. The organic molecule is located at a junction between two metal electrodes or wires and is switched from an ON state to an OFF state by the application of a positive bias across the organic molecule. Such electronic switches have an irreversible switching mechanism and can be toggled once between the ON and OFF state. As such, these electronic switches are useful in programmable read-only memory (PROM).

To provide a reversible switch, an organic molecule having one or more rotating portions (rotors) and two or more stationary portions (stators) has been used. The organic molecule is bi-stable and has two energy states that are separated by an energy or activation barrier. The organic molecule rotates between these energy states when an external electrical field is applied, thus toggling between the ON and the OFF states. Since the electronic switch is reversible, nanoscale electronic devices utilizing the electronic switch are used to provide memory, logic, and communications functions, such as in a ROM-like device or in a reconfigurable system, such as a defect-tolerant communications and logic network.

In addition to organic materials, copper sulfide (Cu₂S) has been shown to exhibit reversible, switching properties in a nanoscale switch. The nanoscale switch includes a layer of copper sulfide sandwiched between a copper electrode and a gold/platinum/titanium electrode. The nanoscale switch is controlled by applying a voltage of less than 0.3 V. The copper sulfide layer is formed electrochemically by depositing a copper layer having a thickness of 120 nm over the copper electrode. The copper is sulfidized to copper sulfide using anodic polarization. The copper sulfide layer can also be deposited by electrochemical reaction/plating, thermal coevaporation, or thermal reaction/annealing techniques. However, these techniques do not produce a copper sulfide layer having optimal properties for use in nanoscale electronic devices because the copper sulfide that is formed is not uniform and consistent. If the copper sulfide layer is deposited electrochemically, good control of the thickness, composition, and uniformity of the layer is not obtained. Likewise, coevaporation of sulfur with copper does not provide monoatomic sulfur to form the desired phase of the copper sulfide layer. Furthermore, these deposition techniques are not compatible with nanofabrication processes.

It would be desirable to form a thin, uniform layer of the metal chalcogenide, such as copper sulfide, for use in a nanoscale electronic device. It would also be desirable to form the metal chalcogenide using a process that is compatible with nanofabrication processes.

### BRIEF SUMMARY OF THE INVENTION

The present invention relates to a method of forming a metal chalcogenide layer. The method includes providing a metal layer and exposing the metal layer to a chalcogen plasma to form a metal chalcogenide layer.

The present invention also relates to a nanoscale electronic device. The nanoscale electronic device includes a substrate, a bottom electrode in contact with the substrate, a metal chalcogenide layer in electrical contact with the bottom electrode, and a top electrode in electrical contact with the metal chalcogenide layer. The metal chalcogenide layer has a thickness ranging from approximately 10 nm to approximately 100 nm.

The present invention also relates to a method of forming a nanoscale electronic device. The method includes providing a substrate and forming a bottom electrode on the substrate. A metal layer is formed in electrical contact with the bottom electrode. The metal layer is exposed to a chalcogen plasma to form a metal chalcogenide layer. A top electrode is then formed in electrical contact with the metal chalcogenide layer.

### BRIEF DESCRIPTION OF THE SEVERAL VIEWS OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1-3 are schematic illustrations of an embodiment of a nanoscale electronic device formed by a method of the present invention; and

FIGS. 4-7 are schematic illustrations of another embodiment of a nanoscale electronic device formed by a method of the present invention.

### DETAILED DESCRIPTION OF THE INVENTION

A method of forming a metal chalcogenide using a chalcogen plasma is disclosed. As used herein, the term “chalcogenide” refers to a binary or multinary compound that includes a chalcogen and a more electropositive element or radical. As used herein, the term “chalcogen” refers to an element of Group VI of the Periodic Table, such as sulfur (S), selenium (Se), or tellurium (Te). The more electropositive element is a metal, as described below. Therefore, as used herein, the phrase “metal chalcogenide” refers to a binary or multinary compound of sulfur, selenium, or tellurium with the metal. While forming copper sulfide as an exemplary metal chalcogenide is described in detail herein, it is understood that the present invention is not limited to copper sulfide. Additional metal chalcogenides may be formed in a similar fashion.

By using a plasma to form the metal chalcogenide, a thickness, composition, and uniformity of the metal chalcogenide may be controlled. As such, uniform and consistent samples of the metal chalcogenide may be produced and the metal chalcogenide may be used in a nanoscale electronic device, such as in a nonvolatile memory device. As used herein, the phrase “nanoscale electronic device” refers to an electronic device having dimensions that range from approximately 10 nm to approximately 100 nm. In contrast, the phrase “micronscale electronic device” refers to an electronic device having dimensions that range from approximately 1 μm to a few μm in size and the phrase “submicronscale electronic device” refers to an electronic device having dimensions that range from approximately 0.04 μm to approximately 1 μm in size. The metal chalcogenide formed using the chalcogen plasma may also be useful in other applications wherd uniform and consistent metal chalcogenides are utilized, such as in integrated circuits of semiconductor chips or in phase transition memory structures that do not utilize crossbar architecture.

The metal chalcogenide may be formed by converting a metal to its corresponding metal chalcogenide. The metal may be present as a layer on a substrate, as described below, but is not limited to such. The metal may include, but is not limited to, copper, silver, indium, antimony, arsenic, gallium, cadmium, tin, and mixtures thereof. As such, the formed metal chalcogenide may be a chalcogenide of copper, silver, indium, antimony, arsenic, gallium, cadmium, tin, or mixtures thereof. The metal may be exposed to the chalcogen plasma, which is generated by introducing a chalcogen source into a plasma chamber. The chalcogen source may be an elemental species of the chalcogen or a compound including the chalcogen. Chalcogen elements and compounds have high vapor pressures and, therefore, are gaseous or sublimable. The chalcogen source may be heated or vaporized in the plasma chamber, thus forming a monoatomic chalcogen species that reacts with the metal to form the metal chalcogenide. The chalcogen source may be present in the plasma chamber with an inert carrier gas, such as argon or helium.

The plasma chamber may be a conventional plasma chamber including, but not limited to, a plasma chamber having a parallel, variable electrode configuration. For instance, the plasma chamber may be a conventional, chemical vapor deposition (CVD)-type plasma chamber used in the semiconductor industry. Operating conditions of the plasma chamber, such as gas flow, gas pressure, plasma power, treatment time, or a temperature of the substrate or plasma chamber, may be controlled to produce a desired thickness and surface roughness of the metal chalcogenide. For instance, the substrate or plasma chamber may be maintained at a temperature ranging from approximately −20° C. to approximately 350° C. The gas flow may range from approximately 1 standard cubic centimeters per minute (sccm) to approximately 50 sccm. The pressure in the plasma chamber may range from approximately 10 mTorr (mT) to approximately 100 mT. The plasma power may range from approximately 30 watts to approximately 1000 watts. In addition, these parameters may be controlled to produce uniform and consistent metal chalcogenides. In other words, different samples of the metal chalcogenide produced using the chalcogen plasma may have a consistent composition, thickness, and uniformity. As such, different samples of the metal chalcogenide may each have similar properties.

In one particular embodiment, the metal is copper and the chalcogen plasma is a sulfur plasma. The sulfur plasma is produced by introducing a stable, elemental species of sulfur (e.g., S₂ or S₈) or hydrogen sulfide (H₂S) into the plasma chamber. The sulfur source is heated or vaporized to produce monoatomic sulfur, which reacts with the copper to form copper sulfide.

By utilizing the chalcogen plasma, a thin layer of the metal chalcogenide can be formed. The formed layer may range from approximately 10 nm to approximately 100 nm in thickness. The metal chalcogenide layer may also have a low surface roughness, such as a peak-to-valley surface roughness ranging from approximately 1 nm to approximately 10 nm.

The metal chalcogenide may exhibit reversible, switching properties when a voltage is applied through the metal chalcogenide. As such, the metal chalcogenide may be used as a switchable material or a switchable layer in the nanoscale electronic device. Since the nanoscale electronic device may be opened and closed multiple times, the nanoscale electronic device may be used in memory bits in a random access memory (RAM). The nanoscale electronic device may also be used in memories, logic devices, multiplexers, demultiplexers, configurable interconnects for integrated circuits, field-programmable gate arrays (FGPAs), cross-bar switches, and communication devices, such as cellular phones, mobile appliances, and personal digital assistants (PDAs).

Utilizing the chalcogen plasma may provide a simple and reliable method of forming the metal chalcogenide because fewer steps are used compared to conventional deposition techniques for forming metal chalcogenides. In addition, forming the metal chalcogenide with the chalcogen plasma is compatible with other nanofabrication processing techniques, such as nanoimprinting, and also with equipment designed for use in the semiconductor industry, such as plasma chambers. Furthermore, since the metal chalcogenide may have a well-controlled thickness, composition, and uniformity, fluctuations in electronic properties between different samples of the metal chalcogenide or between different nanoscale electronic devices having the metal chalcogenide may be minimized. As such, performance of the nanoscale electronic devices may be improved.

As previously described, the metal chalcogenide may be used as the switchable layer in a reversible switch. The switch may include a layer of metal chalcogenide sandwiched between two electrodes. The two electrodes form a junction where one electrode crosses the other electrode at a nonzero angle. The metal chalcogenide connects the two electrodes at the junction. A variety of nanoscale electronic devices and circuits may be produced by assembling a plurality of switches. For instance, a plurality of switches may be assembled to produce crossbar circuit structures, crossbar switch arrays, logic devices, memory devices, and communication and signal routing devices that provide memory, logic, and communications functions. For the sake of example only, the switch may be used in a resistor, a tunneling resistor, a resonant tunneling resistor, a diode, a tunneling diode, a resonant tunneling diode, or a battery, as described in U.S. Pat. No. 6,512,119 to Bratkovski et al., which is assigned to the assignee of the present invention and is incorporated by reference in its entirety herein.

The switches may include crossbar circuit structures and crossbar memory structures, as described in U.S. Pat. Nos. 6,128,214 and 6,256,767 to Kuekes et al. and U.S. Pat. No. 6,458,621 to Beck, which are assigned to the assignee of the present invention and are incorporated by reference in their entirety herein. The crossbar memory structure may include an array of switches that connect a wire in one set of parallel wires to every member of a second set of parallel wires that intersects the first set. The switchable layer formed from the metal chalcogenide may be used in the crossbar circuit structure or the crossbar memory structure in place of switch molecules, such as those described in U.S. Pat. Nos. 6,128,214 and 6,256,767. As such, the metal chalcogenide may be sandwiched between the electrodes or wires of the crossbar memory structure.

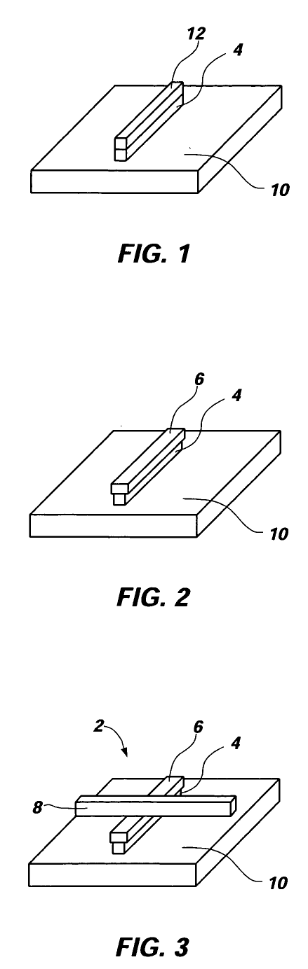

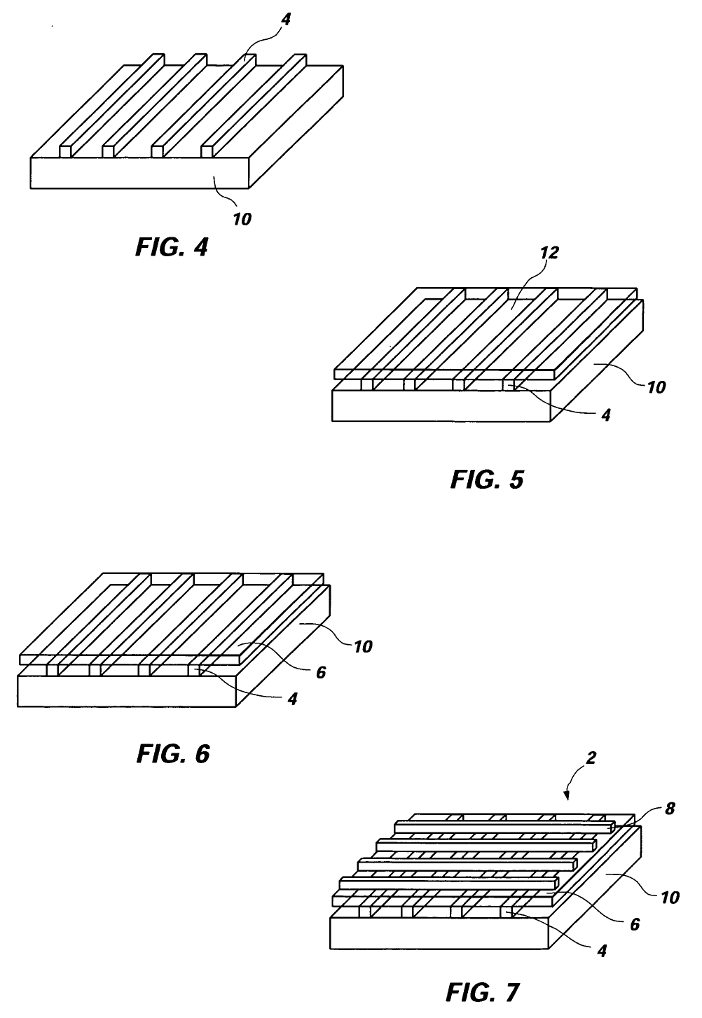

As shown in FIGS. 1-3, a single, crossbar structure 2 may include a bottom electrode 4, a metal chalcogenide layer 6, a top electrode 8, and a substrate 10. More complicated crossbar structures having multiple crossbar structures 2 may also be formed, as shown in FIGS. 4-7. The substrate 10 may be a flat surface formed from an insulative material including, but not limited to, an undoped (i.e., intentionally not doped) semiconductor, silicon nitride, amorphous silicon dioxide (i.e., glass), crystalline silicon dioxide (i.e., quartz), sapphire, silicon carbide, diamond-like carbon (DLC), insulating plastic, polymer, and ceramic (crystalline or amorphous). The insulative material may be used either in bulk form (the entire substrate) or in film form (film grown or deposited on a semiconductor substrate, such as silicon or gallium arsenide).

The bottom electrode 4 may be formed from an electrically-conductive material, such as a semiconductor, metal, or polymer. The bottom electrode 4 may be a single layer or may be a multilayer structure having an adhesive layer and a contact layer. The adhesive layer provides adhesion between the substrate 10 and the contact layer, which functions as the bottom electrode. For the sake of simplicity, the bottom electrode 4 in FIGS. 1-7 is shown as a single layer. The adhesive layer may be formed from a metal, such as from titanium, chromium, tantalum, nickel, vanadium, or mixtures thereof. The thickness of the adhesive layer may range from approximately 1 nm to approximately 50 nm. In one particular embodiment, the adhesive layer is a 5 nm thick layer of titanium. The adhesive layer may be formed by nanoimprinting, shadow masking, or lithographic techniques.

Nanoimprinting techniques are described in U.S. Pat. No. 6,432,740 to Chen, which is assigned to the assignee of the present invention and is incorporated by reference in its entirety herein. Nanoimprinting utilizes compression molding and a pattern transfer process. A mold having nanometer-scale features is pressed into a thin photoresist cast on a substrate, which creates a thickness contrast pattern in the photoresist. After the mold is removed, a lift-off process or an anisotropic etching process is used to transfer the pattern into the entire photoresist thickness by removing the remaining photoresist in the compressed areas. Lift-off processes and etching processes are known in the art. The material of the feature to be formed, such as the metal of the adhesive layer, is deposited in indentations formed by removing the photoresist. The material is deposited by conventional techniques, such as by CVD, physical vapor deposition (PVD), sputtering, or electron beam evaporation. Nanoimprinting may be used to produce features having a feature size of less than approximately 10 nm (sub-10-nm). Nanoimprinting also provides high throughput at a low cost and causes minimal damage to other circuits components on the nanoscale electronic device.

In micron- and submicron-scale electronic devices, shadow masking or lithographic techniques may be used to form the adhesive layer. In shadow masking, a thin, metal sheet having windows may be applied to the substrate 10. The material of the feature to be formed, such as the metal of the adhesive layer, may be applied to the substrate 10 through the windows by a conventional deposition technique including, but not limited to, CVD, PVD, sputtering, or evaporation. Shadow masking may be used to form features having a feature size ranging from approximately 5 μm to approximately 10 μm. However, shadow masking may be unsuitable for forming smaller features, such as sub-micrometer- and nanometer-size features. Lithographic techniques used to pattern the adhesive layer are known in the art and, as such, are not discussed in detail herein. The lithographic techniques may include, but are not limited to, electron beam, laser ablation, focused ion beam (FIB; additive or subtractive), laser-assisted deposition, electron-assisted deposition, photo-assisted deposition, and atomic force microscope/scanning tunneling microscope (AFM/STM)-assisted deposition. The lithographic techniques may be used to form features having submicron feature sizes.

The contact layer may be formed over the adhesive layer. The contact layer of the bottom electrode 4 may include, but is not limited to, platinum, palladium, tungsten, gold, silver, copper, aluminum, molybdenum, titanium, chromium, and mixtures thereof. The contact layer may range in thickness from approximately 5 nm to approximately 100 nm. In one particular embodiment, the contact layer is a 10 nm thick layer of platinum. The contact layer may be formed by nanoimprinting, shadow masking, or lithographic techniques, as previously described.

The metal chalcogenide layer 6 may be formed by depositing a metal layer 12 over the contact layer. The metal layer 12 may be patterned to form a single layer that is in contact with the bottom electrode 4, as shown in FIG. 1. Alternatively, the metal layer 12 may remain unpatterned, as shown in FIG. 5. The metal layer 12 may then be converted to the metal chalcogenide layer 6. The metal layer 12 may include, but is not limited to, copper, silver, indium, antimony, arsenic, gallium, cadmium, tin, and mixtures thereof, as previously described. The metal layer 12 may have a thickness ranging from approximately 5 nm to approximately 50 nm. In one particular embodiment, the metal layer 12 is a 10 nm layer of copper. While the metal layer 12 is shown as a continuous layer in FIGS. 1 and 5, the metal may also be formed as a discontinuous layer. The metal layer 12 may be converted to the metal chalcogenide by exposure to the chalcogen plasma, as previously described. For instance, the substrate 10 having the bottom electrode 4 and the metal layer 12 thereon may be placed in the plasma chamber and exposed to the chalcogen plasma. The flow rate and gas pressure of the chalcogen plasma, the plasma power, the treatment time, and the temperature of the substrate 10 may be controlled to form the desired thickness of the metal chalcogenide layer 6.

After forming the metal chalcogenide layer 6, the top electrode 8 may be formed at a non-zero angle to the bottom electrode 4, completing the crossbar structure 2. For instance, the top electrode 8 may be formed perpendicular to the bottom electrode 4. However, the top electrode 8 and the bottom electrode 4 may be positioned at any non-zero angle relative to one another. The top electrode 8 may be formed from one of the metals disclosed for use in the bottom electrode 4, such as platinum, palladium, gold, silver, copper, aluminum, molybdenum, tungsten, or mixtures thereof. The bottom and top electrodes 4,8 may be formed from the same or different metals. The metal used in the top electrode 8 may be selected in combination with the metal used the bottom electrode 4, since, in some cases, it may be necessary to etch through the top electrode 8 down to the bottom electrode 4. In such cases, it may be possible to etch one electrode without etching the other electrode, such as by selecting the metal of the bottom electrode 4 to etch at a slower rate than that of the top electrode 8. Alternatively, the bottom electrode 4 may be a greater thickness than the top electrode 8 so that etching the top electrode 8 does not unduly limit conductance of the bottom electrode 4. The top electrode 8 may be formed by nanoimprinting, shadow masking, or lithographic techniques, as previously described. The top electrode 8 may be a single layer or may be a multilayer structure, such as a 2-layer structure of platinum and copper. In one particular embodiment, the top electrode 8 is a copper layer. In another embodiment, the top electrode 8 is a two-layer structure of platinum and copper.

In one particular embodiment of the crossbar structure 2, the bottom electrode 4 includes a 5 nm thick layer of titanium as the adhesive layer and a 10 nm thick layer of platinum as the contact layer. The metal layer 12 is a 10 nm thick layer of copper. When this copper layer is exposed to a sulfur plasma, the metal layer 12 is sulfidized to form a layer of copper sulfide as the metal chalcogenide layer 6. The top electrode 8 is a platinum layer.

As previously mentioned, more complicated crossbar structures may be formed. As shown in FIGS. 4-7, multiple bottom electrodes 4 may be formed on the substrate 10. The metal layer 12 may then be formed over the bottom electrodes 4 and converted to the metal chalcogenide layer 6, as previously described. The metal layer 12 may be unpatterned such that the metal layer 12 is in contact with the bottom electrodes 4. As such, the metal chalcogenide layer 6 may be unpatterned. Multiple top electrodes 8 may be formed at a non-zero angle to the bottom electrodes 4, completing the crossbar structure 2. A single cross-point or junction of the bottom electrodes 4 and the top electrodes 8 may be accessed by impressing a voltage on a specific X-axis line and a specific Y-axis line.

To prevent shorting between the top electrode 8 and the contact layer of the crossbar structure 2, the metal layer 12 may expand due to the chalcogen plasma treatment. In other words, the thickness of the metal layer 12 may increase during the conversion of the metal layer 12 to the metal chalcogenide layer 6, which may prevent direct contact between the top electrode 8 and the contact metal. Alternatively, conventional techniques used in the semiconductor industry may be used to prevent shorting, such as filling with insulating material (silicon dioxide) followed by planarization.

Before voltage is applied across the electrodes 4,8, the metal chalcogenide layer 6 is an insulating material and its conductance is low. However, as voltage is applied across the top electrode 8 and the bottom electrode 4, a conducting path may be formed through the metal chalcogenide layer 6. The voltage applied across the top electrode 8 and the bottom electrode 4 may range from approximately 50 mV to approximately 2V. By reversing the voltage, the conducting path may be removed or annihilated from the metal chalcogenide layer 6. For instance, when the metal chalcogenide layer 6 is a copper sulfide layer and a negative voltage is applied to the top electrode 8, copper ions migrate toward the top electrode 8 and are neutralized by electrons flowing from the electrode. The copper may precipitate in the metal chalcogenide layer 6, forming the conducting path. The negative voltage may range from approximately −0.1 V to approximately −2 V. When a positive voltage is applied, the precipitated copper may be ionized and may dissolve back into the metal chalcogenide layer 6. As such, the conducting path may be removed from the metal chalcogenide layer 6. The positive voltage may range from approximately 0.05 V to approximately 2 V. By cycling the polarity and magnitude of the voltage beyond appropriate threshold values, the switch may be reversibly toggled between the ON and OFF states.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the spirit and scope of the invention as defined by the following appended claims.

1. A method of forming a metal chalcogenide layer, comprising:
providing a metal layer; and
exposing the metal layer to a chalcogen plasma to form a metal chalcogenide layer.

2. The method of claim 1, wherein providing a metal layer comprises providing a metal layer selected from the group consisting of copper, silver, indium, antimony, arsenic, gallium, cadmium, tin, and mixtures thereof.

3. The method of claim 1, wherein providing a metal layer comprises providing the metal layer on a substrate.

4. The method of claim 1, wherein providing a metal layer comprises forming the metal layer by nanoimprinting.

5. The method of claim 1, wherein exposing the metal layer to a chalcogen plasma comprises providing the chalcogen plasma selected from the group consisting of a sulfur plasma, a selenium plasma, and a tellurium plasma.

6. The method of claim 1, wherein exposing the metal layer to a chalcogen plasma comprises exposing copper to a sulfur plasma to form copper sulfide.

7. The method of claim 1, wherein exposing the metal layer to a chalcogen plasma to form a metal chalcogenide layer comprises controlling at least one of a gas flow, gas pressure, plasma power, treatment time, and a temperature of the substrate in a plasma chamber to form the metal chalcogenide layer.

8. The method of claim 7, wherein forming the metal chalcogenide layer comprises forming the metal chalcogenide layer having a thickness ranging from approximately 10 nm to approximately 100 nm.

9. The method of claim 1, wherein exposing the metal layer to a chalcogen plasma comprises forming a monoatomic chalcogen species that reacts with the metal layer to form the metal chalcogenide layer.

10. A nanoscale electronic device, comprising:
a substrate, a bottom electrode in contact with the substrate, a metal chalcogenide layer in electrical contact with the bottom electrode, and a top electrode in electrical contact with the metal chalcogenide layer, wherein the metal chalcogenide layer has a thickness ranging from approximately 10 nm to approximately 100 nm.

11. The nanoscale electronic device of claim 10, wherein the metal chalcogenide layer has a peak-to-valley surface roughness ranging from approximately 1 nm to approximately 10 nm.

12. The nanoscale electronic device of claim 10, wherein the metal of the metal chalcogenide layer is selected from the group consisting of copper, silver, indium, antimony, arsenic, gallium, cadmium, tin, and mixtures thereof.

13. The nanoscale electronic device of claim 10, wherein the chalcogen of the metal chalcogenide layer is selected from the group consisting of sulfur, selenium, and tellurium.

14. The nanoscale electronic device of claim 10, wherein the metal chalcogenide comprises copper sulfide.

15. The nanoscale electronic device of claim 10, wherein the bottom electrode comprises an adhesive layer formed from a metal selected from the group consisting of titanium, chromium, tantalum, nickel, vanadium, and mixtures thereof.

16. The nanoscale electronic device of claim 10, wherein the bottom electrode comprises a contact layer formed from a metal selected from the group consisting of platinum, palladium, tungsten, gold, silver, copper, aluminum, molybdenum, titanium, chromium, and mixtures thereof.

17. The nanoscale electronic device of claim 10, wherein the top electrode comprises a metal selected from the group consisting of platinum, palladium, tungsten, gold, silver, copper, aluminum, molybdenum, titanium, chromium, and mixtures thereof.

18. A method of forming a nanoscale electronic device, comprising:
providing a substrate;
forming a bottom electrode on the substrate;
forming a metal layer in electrical contact with the bottom electrode;
exposing the metal layer to a chalcogen plasma to form a metal chalcogenide layer; and
forming a top electrode in electrical contact with the metal chalcogenide layer.

19. The method of claim 18, wherein forming a bottom electrode on the substrate comprises forming an adhesive layer from a metal selected from the group consisting of titanium, chromium, tantalum, nickel, vanadium, and mixtures thereof.

20. The method of claim 18, wherein forming a bottom electrode on the substrate comprises forming a contact layer from a metal selected from the group consisting of platinum, palladium, tungsten, gold, silver, copper, aluminum, molybdenum, titanium, chromium, and mixtures thereof.

21. The method of claim 18, wherein forming a bottom electrode on the substrate comprises forming the bottom electrode by nanoimprinting.

22. The method of claim 18, wherein forming a metal layer in electrical contact with the bottom electrode comprises forming the metal layer selected from the group consisting of copper, silver, indium, antimony, arsenic, gallium, cadmium, tin, and mixtures thereof.

23. The method of claim 18, wherein forming a metal layer in electrical contact with the bottom electrode comprises forming the metal layer by nanoimprinting.

24. The method of claim 18, wherein exposing the metal layer to a chalcogen plasma comprises providing the chalcogen plasma selected from the group consisting of a sulfur plasma, a selenium plasma, and a tellurium plasma.

25. The method of claim 18, wherein exposing the metal layer to a chalcogen plasma comprises forming a monoatomic chalcogen species that reacts with the metal layer to form the metal chalcogenide.

26. The method of claim 18, wherein exposing the metal layer to a chalcogen plasma to form a metal chalcogenide layer comprises forming the metal chalcogenide from copper sulfide.

27. The method of claim 18, wherein forming a top electrode in electrical contact with the metal chalcogenide layer comprises forming the top electrode from a metal selected from the group consisting of platinum, palladium, tungsten, gold, silver, copper, aluminum, molybdenum, titanium, chromium, and mixtures thereof.

28. The method of claim 18, wherein forming a top electrode in electrical contact with the metal chalcogenide layer comprises forming the top electrode by nanoimprinting.
